(19) United States
(12) Patent Application Publication
(10) Pub. No.: US 2026/0134180 A1
(43) Pub. Date: May 14, 2026

(54) DEVICES AND METHODS FOR PURPOSE IDENTIFICATION OF GRAPHIC DESIGN SYSTEM (GDS) LAYERS IN LAYOUT DESIGNS

(71) Applicant: Samsung Electronics Co., Ltd., Suwon-si (KR)

(72) Inventors: Amar Kumar Yadav, Bengaluru (IN); Joshua Pushparaj Christ Doss, Bengaluru (IN); Zameer Iqbal, Bengaluru (IN)

(21) Appl. No.: 19/012,141

(22) Filed: Jan. 7, 2025

(30) Foreign Application Priority Data
Nov. 8, 2024 (IN) 202441086206

(51) Int. Cl. G06F 30/31; G06F 30/323; G06F 30/392

(52) U.S. Cl. CPC G06F 30/31; G06F 30/323; G06F 30/392

(57) ABSTRACT

Device and methods for purpose identification of Graphic Design System (GDS) layers in layout designsA method comprising: generating, by an electronic device, a LayerMatrix using a layer technology file, wherein the layer technology file includes layer information; generating, by the electronic device, a polygon shape and a label using a set in the LayerMatrix, wherein the set includes a layer and a purpose of the layer; generating, by the electronic device, a GDS using the polygon shape and the label in the LayerMatrix; extracting, by the electronic device, a layout netlist from the GDS using a layout netlist extraction process; filtering out, by the electronic device, a list from the layout netlist based on a designed labelling pattern, wherein the list includes label, port, and device information; and mapping, by the electronic device, the list to the layer information in the layer technology file.

### CROSS-REFERENCE TO RELATED APPLICATIONS

This U.S. non-provisional patent application claims priority under 35 U.S.C. § 119 to Indian Patent Application No. 202441086206, filed on Nov. 8, 2024, in Office of the Controller General of Patents, Designs & Trademarks Department for Promotion of Industry and Internal Trade Ministry of Commerce & Industry (Indian Patent Office), the entire contents of which are hereby incorporated by reference.

### TECHNICAL FIELD OF THE INVENTION

Embodiments of the inventive concepts disclosed herein relate to a Process Design Kit (PDK)/layout design for a semiconductor device, and more particularly to electronic devices and methods for identifying purposes of Graphic Design System (GDS) layers used in the layout design of the semiconductor device.

### BACKGROUND OF THE INVENTION

Process Design Kit (PDK) is a standard package (for a semiconductor device design) that includes components (e.g., information, programs, commands, models, and/or software) like a device library and Physical Verification Check (PVC), such as Layout Versus Schematic (LVS), Design Rules Checking (DRC), Parasitic Extraction (PEX), and so on. A mathematical model may be representative of devices (like Spice models) for each process node (each manufacturing process) of the semiconductor device. All Process Design Kit (PDK) components are compliant with technology specs as concerns a manufacturing facility (e.g., a Foundry Fab) process and as put forward (e.g., as proposed) by a process architecture and/or a user (e.g., a designer or a technology development team of the semiconductor device). The designs (designed based on the PDK) may be made and sent to the manufacturing facility (e.g., the Foundry Fab) to fabricate the semiconductor device.

The PDK may be compliant with and may be present in a tool environment (for the semiconductor device design). These currently used tools (for the semiconductor design) may be called (industry-standard) Electronic Design Automation (EDA) tools. Each of the PDK components may have a dependency on the EDA tool with respect to syntax, functional support, and flow. The environment of the EDA tools may have PDK integrated into it and may enable the complete development of foundational IPs, analog IPs, and general IPs with respect to schematic closure, spice simulation, Automatic Computer-Aided Design (Auto CAD) development of layouts, diagnostic checks for the DRC and LVS, as well as final layout PEX. Thus, the tool environment supports the semiconductor device designs when the PDK is released. At the time of PDK release, either at the design level or the EDA level, there is no information for identification of the layers (of the semiconductor device design) and the purpose of the layers. The lack of information for the identification of the layers may create an issue for going back again (e.g., issue for review, modification, correction, and/or re-referral of specific layers), which makes the design process unnecessarily complicated. Thus, in those cases, going back and studying how every component and device is connected may be complicated (almost impossible).

Existing systems (e.g., devices or methods) may use auxiliary layers for the identification of different types of devices in the layout design using physical verification, such as LVS and so on. Thus, the existing systems may use layers and names to identify them in the layout design. For example, the existing systems may define layer A, and layer A is (at least a part of) a device inductor. Thus, the existing systems use layer A and can identify a layout design as the device inductor if layer A is present.

The existing systems may exclude extra devices present (may not use unnecessary layers) in the schematic design or in the layout design before LVS runs. The existing systems may use unique labels in the schematic design and in the layout design to define the nets (i.e., comparison of labels in the schematic design vs. labels in the layout design). The labels used in the existing systems may be unique from (e.g., incompatible with) each other in the schematic design and the layout design.

There is no standard to keep the layer naming convention across the process nodes in the PDK. Also, there is no standard to keep the same Graphic Design System (GDS) layer numbers for specific uses/purposes across the different process nodes in the PDK. Thus, one number may be assigned to one or more GDS layer numbers in different process nodes. If wrong labelling or misrecognition of layers occurs due to the absence of standards for layer naming or layer numbering, the PVC (layout schematic extraction checker) may fail to extract the nets, ports, and devices from the layout design. Therefore, information, such as the nets, ports, and devices, may need to be recognized correctly by using the LVS.

Due to non-standardized layer naming conventions and/or lack of proper documentation, substantial effort may be needed to go through the process node documents to get information about the usages and purposes of the GDS layers (i.e., recognition layers, port layers, label layers, etc.) for creating layout designs and finding the usages and purposes of the different GDS layers present in the PDK.

This may restrict some flows related to the PDK Quality Assurance (QA) process for generating layout designs and subsequent checks. Therefore, there may be a lack of information about which layer and the purpose of the layer should be attached to which routing metal layer to recognize the port/pin. The testCases can be generated with the available information. The testCases can be automated; if the testCases are schematics, that will be layout vs. schematic (LVS) compliance. The LVS compliant testCases may provide information about, such as, the correct pin, port, and recognition layer. These testCases may be needed for the PEX, but they can also be used for any other PDK component. All these testCases that are LVS compliant may be created due to this ‘extraction capability’ and save the complete churn of looking into the process node documents for understanding the purpose of the layer.

Layout migration, which is usually a part of a design migration, may be challenging due to the different layer naming and layer purpose naming conventions used across the process nodes; thus, the same (identical) design may not be easily migrated from one process node to another and can give warnings or errors as well.

Therefore, there is no standard in this area/domain, called PDK, across the globe to keep the same GDS layer number for certain layers and the specific purpose of these layers. For example, there are specific naming conventions for these layers in different organizations. Therefore, there were numbers assigned to each layer, but the numbers can vary depending on the organizations. Even the numbers can change from process to process. So, (even in the same organization,) there is no standard to keep those numbers constant/same/standard throughout the process nodes.. There is a next stage called PVC, such as, but not limited to, LVS, DRC, and so on. Once the designs are checked with the PVC, if the right layers are not used for defining the device place, defining the labels or pins, or for the recognition of the devices while the designs are running, then it results in recognizing those devices, labels, and pins that cause the failure. This failure may come into the picture at a (very) later stage. Then there may be a need to go back and update it (the designs) and debug it. Debugging may be complicated because, again, there may be a need to go into the details of the PVC. The details may provide information about which layer is used for what purpose, and accordingly, there is a need to review such details to correct the design. Users may also need to go into the document (e.g., the process node document) due to all these limitations. Hence, the organization, or PDK, may need to provide all the details related to layers for each process node. This makes the method (the conventional debugging method) complicated, as there is a need to either go through the document again or remember all the details related to the used layers.

Hence, there is a need in the art for solutions that will overcome the above-mentioned drawback(s), among others.

### OBJECT OF THE INVENTION

One of the objects of the embodiments of the inventive concepts herein is to disclose devices and methods for identifying one or more uses and purposes of Graphic Design System (GDS) layers used in a layout design.

Another object of the embodiments of the inventive concepts herein is to disclose devices and methods for providing information about the layers with the purpose of the layers directly from the GDS in the layout design.

Another object of the embodiments of the inventive concepts herein is to disclose devices and methods for extracting the information for identification of net connectivity and device recognition in the layout design.

Another object of the embodiments of the inventive concepts herein is to disclose devices and methods for generating a LayerMatrix using a layer technology file. The layer technology file may contain layer information.

Another object of the embodiments of the inventive concepts herein is to disclose devices and methods for generating one or more GDS using one or more polygon shapes and generated labels in the generated LayerMatrix.

Another object of the embodiments of the inventive concepts herein is to disclose devices and methods for extracting a layout netlist from the generated one or more GDS using a layout netlist extraction process.

Another object of the embodiments of the inventive concepts herein is to disclose device and methods for generating testCases and a layer map file for a design layout migration in different Electronic Design Automation (EDA) tools. The objects of the embodiments of the inventive concepts herein are not limited to the above-mentioned objects.

### SUMMARY OF THE INVENTION

Accordingly, the embodiments herein provide methods identifying a purpose of at least one Graphic Design System (GDS) layer used in a layout design, comprising: generating, by an electronic device, a LayerMatrix using a layer technology file, wherein the layer technology file includes layer information; generating, by the electronic device, a polygon shape and a label using a set in the LayerMatrix, wherein the set includes a layer and a purpose of the layer; generating, by the electronic device, a GDS using the polygon shape and the label in the LayerMatrix; extracting, by the electronic device, a layout netlist from the GDS using a layout netlist extraction process; filtering out, by the electronic device, a list from the layout netlist based on a designed labelling pattern, wherein the list includes label information, port information, and device information; and mapping, by the electronic device, the list to the layer information in the layer technology file.

Accordingly, the embodiments herein provide an electronic device for identifying a purpose of at least one Graphic Design System (GDS) layer used in a layout design, comprising: a processor; a communication module; and a memory module, wherein the processor is electrically connected to the memory module, wherein the communication module is configured to enable the electronic device to communicate with an external device, and wherein the processor is configured to: generate a LayerMatrix using a layer technology file, wherein the layer technology file includes layer information; generate one or more polygon shapes and a label using set in the LayerMatrix, wherein the set includes a layer and a purpose of the layer; generate one or more Graphic Design System (GDS) using the one or more polygon shapes and the label in the LayerMatrix; extract a layout netlist from the one or more GDS using a layout netlist extraction process; filter out a list from the layout netlist based on a designed labelling pattern, wherein the list includes label information, port information, and device information; and map the list to the layer information in the layer technology file.

These and other aspects of the embodiments herein will be better appreciated and understood when considered in conjunction with the following description and the accompanying drawings. It should be understood, however, that the following descriptions, while indicating at least one embodiment and numerous specific details thereof, are given by way of illustration and not of limitation. Many changes and modifications may be made within the scope of the embodiments herein without departing from the spirit thereof, and the embodiments herein include all such modifications.

### BRIEF DESCRIPTION OF DRAWINGS

The embodiments disclosed herein are illustrated in the accompanying drawings, throughout which like reference letters may indicate the same corresponding parts in the various figures unless clearly stated otherwise. The embodiments herein will be better understood from the following description with reference to the drawings, in which:

FIG. 1 depicts an electronic device for identifying a purpose of Graphic Design System (GDS) layers used in a layout design, according to embodiments as disclosed herein;

FIG. 2 is a flowchart depicting a method for identifying the purpose of the GDS layers used in the layout design, according to embodiments as disclosed herein;

FIG. 3A depicts an example of a section of the LayerMatrix, according to embodiments as disclosed herein;

FIG. 3B depicts an example of a section of the LayerMatrix along with Sets, according to embodiments as disclosed herein;

FIG. 4 depicts an example of a section of the GDS, according to embodiments as disclosed herein;

FIG. 5 depicts an example of a section of a Layout Extracted Netlist (LEN), according to embodiments as disclosed herein;

FIG. 6A depicts a layer combination for a process node for device/pin/label recognition in Back End of Line (BEOL) layer mapping and VIAs layer mapping, and FIG. 6B provides an enlarged view of the example depicted in FIG. 6A, according to embodiments as disclosed herein;

FIG. 7A depicts a use case for a Process Design Kit (PDK) Quality Assurance (QA) testCases generation in a BEOL testCases extracted netlist, according to embodiments as disclosed herein;

FIG. 7B depicts a use case for the PDK QA testCases generation in a VIA testCases extracted netlist, according to embodiments as disclosed herein; and

FIG. 8 depicts a use case for the design layout migration for the BEOL layer mapping, according to embodiments as disclosed herein.

### DETAILED DESCRIPTION OF THE INVENTION

The embodiments herein and the various features and advantageous details thereof are explained more fully with reference to the non-limiting embodiments that are illustrated in the accompanying drawings and detailed in the following description. Descriptions of well-known components and processing techniques may be omitted so as to not unnecessarily obscure the embodiments herein. The examples used herein are intended merely to facilitate an understanding of ways in which the embodiments herein may be practiced and to further enable those of skill in the art to practice the embodiments herein. Accordingly, the examples should not be construed as limiting the scope of the embodiments herein.

For the purposes of interpreting this specification, the definitions (as defined herein) will apply and whenever appropriate the terms used in singular will also include the plural and vice versa. It is to be understood that the terminology used herein is for the purposes of describing particular embodiments only and is not intended to be limiting. The terms “comprising”, “having” and “including” are to be construed as open-ended terms unless otherwise noted.

The words/phrases “exemplary”, “example”, “illustration”, “in an instance”, “and the like”, “and so on”, “etc.”, “etcetera”, “e.g.,”, “i.e.,” are merely used herein to mean “serving as an example, instance, or illustration.” Any embodiment or implementation of the present subject matter described herein using the words/phrases “exemplary”, “example”, “illustration”, “in an instance”, “and the like”, “and so on”, “etc.”, “etcetera”, “e.g.,”, “i.e.,” is not necessarily to be construed as preferred or advantageous over other embodiments.

Embodiments herein may be described and illustrated in terms of blocks which carry out a described function or functions. These blocks, which may be referred to herein as managers, units, modules, hardware components or the like, are physically implemented by analog and/or digital circuits such as logic gates, integrated circuits, microprocessors, microcontrollers, memory circuits, passive electronic components, active electronic components, optical components, hardwired circuits and the like, and may optionally be driven by a firmware. The circuits may, for example, be embodied in one or more semiconductor chips, or on substrate supports such as printed circuit boards and the like. The circuits constituting a block may be implemented by dedicated hardware, or by a processor (e.g., one or more programmed microprocessors and associated circuitry), or by a combination of dedicated hardware to perform some functions of the block and a processor to perform other functions of the block. Each block of the embodiments may be physically separated into two or more interacting and discrete blocks without departing from the scope of the disclosure. Likewise, the blocks of the embodiments may be physically combined into more complex blocks without departing from the scope of the disclosure.

It should be noted that elements in the drawings are illustrated for the purposes of this description and ease of understanding and may not have necessarily been drawn to scale. For example, the flowcharts/sequence diagrams illustrate the method in terms of the steps required for understanding of aspects of the embodiments as disclosed herein. Furthermore, in terms of the construction of the device, one or more components of the device may have been represented in the drawings by conventional symbols, and the drawings may show only those specific details that are pertinent to understanding the present embodiments so as not to obscure the drawings with details that will be readily apparent to those of ordinary skill in the art having the benefit of the description herein. Furthermore, in terms of the system, one or more components/modules which comprise the system may have been represented in the drawings by conventional symbols, and the drawings may show only those specific details that are pertinent to understanding the present embodiments so as not to obscure the drawings with details that will be readily apparent to those of ordinary skill in the art having the benefit of the description herein.

The accompanying drawings are used to help easily understand various technical features and it should be understood that the embodiments presented herein are not limited by the accompanying drawings. As such, the present disclosure should be construed to extend to any modifications, equivalents, and substitutes in addition to those which are particularly set out in the accompanying drawings and the corresponding description. Usage of words such as first, second, third, etc., to describe components/elements/steps is for the purposes of this description and should not be construed as sequential ordering/placement/occurrence unless specified otherwise.

The embodiments of the inventive concepts herein disclose electronic devices and methods for identifying layers and purposes of the layers used in a layout design. These layers and the purposes of the layers may be specific to a Process Design Kit (PDK)/a process node, and these (the layers and the purposes of the layers) may need to be identified in PDK documents.

Embodiments of the inventive concepts herein disclose electronic devices and methods for identifying one or more uses and properties of an already defined GDS layer. The embodiments may not define any layers. For example, the disclosed embodiments may not know about (may not initially recognize) layer A. The disclosed embodiment may first identify layer A and the use/purpose of the layer A. Thus, the identification of the layers is important.

Embodiments of the inventive concepts herein disclose electronic devices and methods for providing information about the layers with the purposes of the layers directly from a Graphic Design System (GDS) in the layout design.

Embodiments of the inventive concepts herein disclose electronic devices and methods for extracting the information (from the GDS) for identification of net connectivity and device recognition in the layout design.

Embodiments of the inventive concepts herein disclose electronic devices and methods for identifying the layer names and the purposes of the layers for a process node.

Embodiments of the inventive concepts herein disclose electronic devices and methods that use unique layout structures and label naming patterns to identify the uses/purposes of the GDS layers. The embodiments may use unique labels with respect to each layout structure and layer used in the layout design.

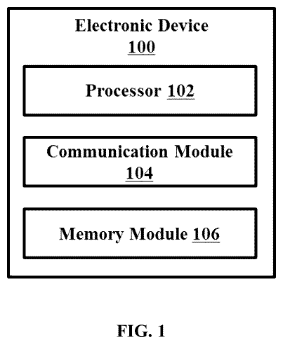

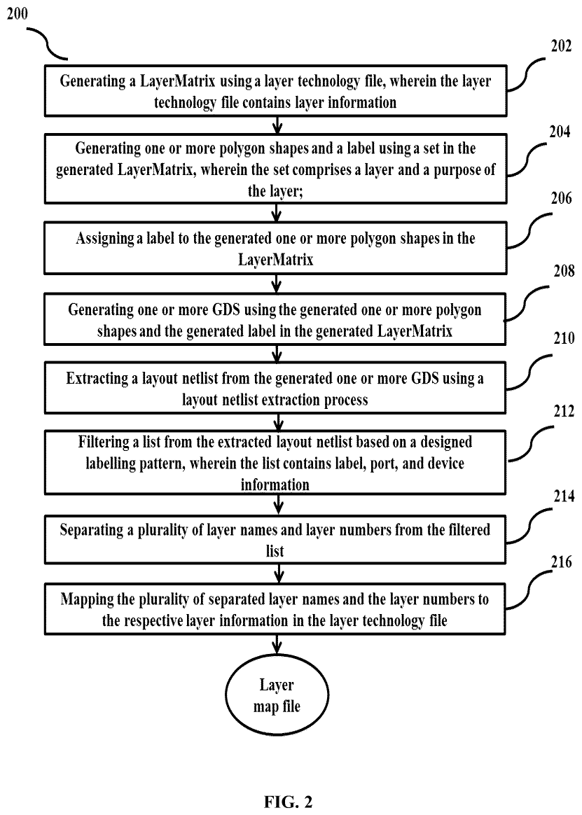

FIG. 1 depicts an electronic device 100 for identifying the purpose of at least one GDS layer used in the layout design. The electronic device 100 may comprise a processor 102, a communication module 104, and a memory module 106. The processor 102 may be (electrically) connected to (e.g., coupled with) the memory module 106. The electronic device 100 can be a real-world device (e.g., a hardware device). Examples of the electronic device 100 can be, but are not limited to, a desktop, a laptop, a smartphone, a personal digital assistant, a wearable device, a kitchen appliance, a smart appliance, or any other device that can capture media (such as, but not limited to, images, videos, animations, and so on).

In the embodiment shown herein, the processor 102 can generate a LayerMatrix using (based on) a layer technology file. The layer technology file may contain layer information. The processor 102 can generate one or more polygon shapes in the generated LayerMatrix. The processor 102 can assign a label to the generated one or more polygon shapes in the LayerMatrix. A Set may comprise a layer and a purpose of the layer. The LayerMatrix may comprise, for example, a possible combination of three Sets of Set1, Set2, and Set3 with two columns. The possible combinations may each refer to a layer with a specific purpose used in the layout design. For example, the Set1 may comprise a physical layer and a (possible) purpose of the physical layer, the Set2 may comprise a (possible) label layer and a purpose of the label layer, and the Set3 may comprise a (possible) device recognition layer and a purpose of the device recognition layer. The processor 102 can generate one or more GDSs using the generated one or more polygon shapes and the generated label in the generated LayerMatrix. The one or more polygon shapes of the GDS may be generated from the Set1 and the Set3 of each row of the LayerMatrix. The labels may be generated from the Set1, the Set2, and the Set3 of each row of the LayerMatrix with a delimiter to differentiate between the layer and the purpose of the layer. The processor 102 can generate one or more GDSs, wherein the generated GDSs comprise a translation of the generated one or more polygon shapes (and the generated label) into a GDS format (e.g., a GDS layer number). The processor 102 can extract a layout netlist from the generated one or more GDSs using a layout netlist extraction process. The layout netlist may be extracted using the layout netlist extraction process run by a Layout Versus Schematic (LVS) tool. The processor 102 can filter out a list from the extracted layout netlist based on a designed labeling pattern. The list may contain label, port, and device information. The processor 102 can separate a plurality of layer names and layer numbers from the filtered list. The processor 102 can map the plurality of separated layer names and layer numbers to the respective layer information in the layer technology file.

In the embodiment shown herein, the processor 102 may comprise one or more microprocessors, circuits, and other hardware configured for processing. The processor 102 can be configured to execute instructions stored in the memory module 106.

The processor 102 can include, for example, a single processor, a plurality of processors, multiple homogeneous or heterogeneous cores, multiple Central Processing Units (CPUs) of different kinds, microcontrollers, special media, and/or other accelerators. The processor 102 may be, for example, an Application Processor (AP), a graphics-only processing unit such as a Graphics Processing Unit (GPU), a Visual Processing Unit (VPU), and/or an Artificial Intelligence (AI)-dedicated processor such as a Neural Processing Unit (NPU).

In the embodiment shown herein, the communication module 104 may be configured to enable communication between the electronic device 100 and at least one external entity (such as, but not limited to, a server) through a network or cloud. The external entity (e.g., server) may be configured or programmed to execute the instructions of the electronic device 100. The communication module 104 through which the electronic device 100 and the external entity (e.g., server) communicate may be in the form of either a wired network, a wireless network, or a combination thereof. The wired and wireless communication networks may comprise, but are not limited to, Global Positioning System (GPS), Global System for Mobile Communications (GSM), Local Area Network (LAN), Wireless Fidelity (Wi-Fi) compatibility, Bluetooth Low Energy (BLE), Near-field Communication (NFC), and so on. The wireless communication network may comprise, for example, Bluetooth (registered trademark), Zonal Intercommunication Global Standard (ZigBee) (registered trademark), short-range wireless communication such as Ultra-wideband (UWB), medium-range wireless communication such as Wi-Fi (registered trademark), and/or long-range wireless communication such as Third Generation (3G), Fourth Generation (4G), and/or Worldwide Interoperability for Microwave Access (WiMAX) (registered trademark), according to the usage environment.

In the embodiment shown herein, the memory module 106 may comprise one or more volatile and non-volatile memory components that are capable of storing data and instructions to be executed. Examples of the memory module 106 can be, but are not limited to, NAND (e.g., NAND Flash Memory), embedded Multimedia Card (eMMC), Secure Digital (SD) cards, Universal Serial Bus (USB), Serial Advanced Technology Attachment (SATA), Solid-State Drive (SSD), and so on. The memory module 106 may include one or more computer-readable storage media (e.g., non-volatile storage elements). Examples of non-volatile storage elements may include magnetic hard disks, optical discs, floppy discs, flash memories, or forms of Electrically Programmable Read-Only Memories (EPROM) or Electrically Erasable and Programmable Read-Only Memories (EEPROM). The memory module 106 may, in some examples, include (e.g., may be considered) a non-transitory storage medium. The term “non-transitory” may indicate that the storage medium is not embodied in a carrier wave or a propagated signal. However, the term “non-transitory” should not be interpreted to mean that the memory module 106 is non-movable. In certain examples, a non-transitory storage medium may store data that can, over time, change (e.g., in Random Access Memory (RAM) or cache).

Although FIG. 1 shows various hardware components of the electronic device 100, but it is to be understood that the embodiments of the electronic device 100 are not limited thereto. In some embodiments, the electronic device 100 may include less or more components. Further, the labels or names of the components are used only for illustrative purposes and do not limit the scope of the invention. One or more components can be combined to perform the same or substantially similar function in the electronic device 100.

In some embodiments, every process node or technology node (e.g., manufacturing processes of a semiconductor device) may have multiple layers (which may be, for example, in the thousands). Specific layers may be selected (among the multiple layers) and one LayerMatrix may be generated based on the information related to the specific layers, such as, but not limited to, the names of the physical layers and their combinations. A LayerMatrix generator may generate the LayerMatrix (based on the information related to the specific layers). The generated LayerMatrix may have layer property-specific and unique polygon shapes, and label name patterning may be further used as an input to a shape generator to generate the GDS. The shape generator may generate polygon shapes using the information present in the table of LayerMatrix, such as physical shapes in the EDA tool. The generated shape (e.g., polygon shape) may be called testCases. These testCases can be specific to the LayerMatrix. Thus, each line may have a certain combination of layers, may have a property-specific layer, and may generate the polygon shape. The polygon structure may assign layer properties to specific layer text and label patterns. Here, “polygon” and “polygon shape” refer to the same. Also, “polygon structure” can mean all polygons (including polygons that shape, shape, and not assign properties only). Therefore, the disclosed embodiment may not make the shape (e.g., the polygon shape) only, but may make the polygon shape and quote the right label on (top of) the shape (e.g., the polygon shape). Therefore, the physical shapes (testCases) may get translated in the GDS format. Thus, label may also get translated during the translation of the GDS format(Layers with polygon shapes and layers that assign labels, both are translated into GDS format). Further, certain combinations of layers with polygon and layers used to assign property may be a need to be recognized correctly by using the LVS with some specific command that may call it a query. So, after performing the LVS run on the translated GDS format, the query may give some specific outputs. The devices, ports, pins, and labels can be recognized, and the outputs can be given in the standard format called Layout Extracted Netlist (LEN). Therefore, the labels, ports, and devices that can be recognized from the LEN using the information may comprise, for example, thousands of different shapes. The fetched information about the layers may comprise the previous information about these testCases, such as, what layer was used for what purpose. Further, the outputs can be sorted and filtered using the information. Further, the information can be segregated and separated into layer names and layer numbers in a Graphical User Interface (GUI) tool. The layer numbers may be aligned. Further, the layer numbers can be mapped to the GDS layer number and the data type. Finally, a layer map file may be received as a result of mapping using the disclosed method and can be used for (any) other purposes. Therefore, designers of the semiconductor device can use the generated testCases and the layer map file for the design layout migration in different EDA tools and for providing prior information during the design cycle. Thus, the layer map file can be used in various applications in various (any) manners.

FIG. 2 is a flowchart depicting a method 200 for identifying the purpose of at least one GDS layer used in the layout design. The operations (202, 204, 206, 208, 210, 212, 214, and 216) may be handled by the processor 102. At step 202, the method 200 may generate a LayerMatrix using a layer technology file. The layer technology file may contain layer information. The LayerMatrix may comprise a possible combination of three Sets of Set1, Set2, and Set3 with two columns. The possible combinations may refer to the layer with a specific purpose used in the layout design. The Set may comprise a layer and a purpose of the layer. For example, the Set1 may comprise a physical layer and a (possible) purpose of the physical layer, the Set2 may comprise a (possible) label layer and a purpose of the label layer, and the Set3 may comprise a (possible) device recognition layer and a purpose of the device recognition layer. At step 204, the method 200 may generate one or more polygon shapes in the generated LayerMatrix. At step 206, the method 200 may assign a label to the generated one or more polygon shapes in the LayerMatrix. At step 208, the method 200 may generate one or more GDSs using the generated one or more polygon shapes and the generated label in the generated LayerMatrix. The one or more polygon shapes of the GDSs may be generated from the Set1 and the Set3 of each row of the LayerMatrix. The labels may be generated from the Set1, the Set2, and the Set3 of each row of the LayerMatrix with a delimiter to differentiate between the layer and the purpose of the layer. The method of generating the one or more GDSs may comprise a translation of the generated one or more polygon shapes into a GDS format and a translation of the generated label into the GDS format (e.g., the GDS layer number). At step 210, the method 200 may extract a layout netlist from the generated one or more GDSs using a layout netlist extraction process. At step 212, the method 200 may filter a list from the extracted layout netlist based on a designed labelling pattern. The list may contain label, port, and device information. At step 214, the method 200 may separate a plurality of layer names and layer numbers from the filtered list. At step 216, the method 200 may map the plurality of separated layer names and the layer numbers to the respective layer information in the layer technology file. The layer map file may be generated (received) as a result of the mapping of the method 200 and can be used for various purposes.

The various actions in the method 200 may be performed in the order presented, in a different order, or simultaneously. Further, in some embodiments, some actions listed in FIG. 2 may be omitted.

The one or a plurality of processors may control the processing of the input data in accordance with a predefined operating rule or artificial intelligence (AI) model stored in the non-volatile memory and/or the volatile memory. The predefined operating rule or artificial intelligence model may be provided through (machine) training or (machine) learning.

Here, being provided through training or learning means that a predefined operating rule or AI model of a desired characteristic may be made by applying a learning (or a training) algorithm to a plurality of learning data. The learning (or the training) may be performed in a device itself, in which AI model, according to an embodiment, is performed, and/or may be implemented through a separate server or system.

The learning (or the training) algorithm can be a method for training a predetermined target device (for example, a robot) using a plurality of learning data to cause, allow, or control the target device to make a determination or prediction. Examples of learning (or training) algorithms may include, but are not limited to, supervised learning, unsupervised learning, semi-supervised learning, or reinforcement learning.

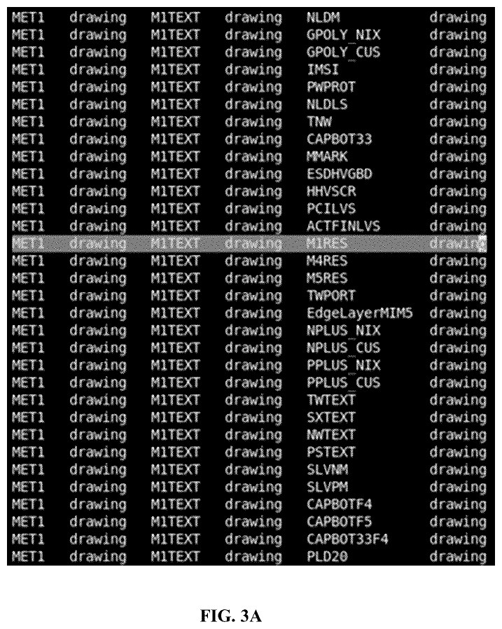

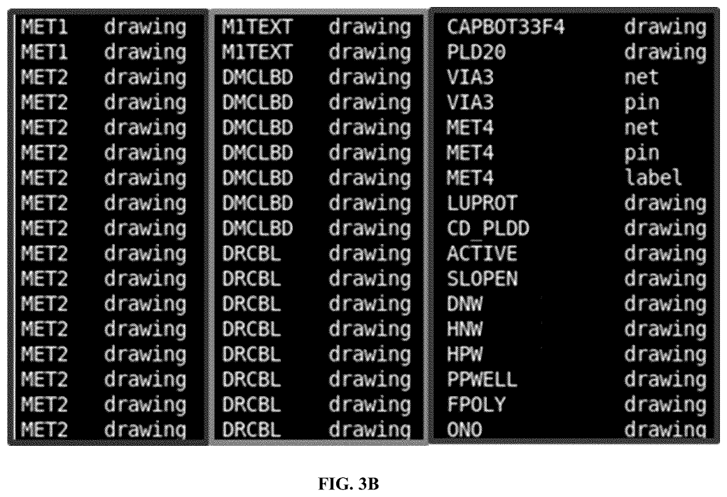

FIG. 3A depicts an example of a section of the LayerMatrix. The LayerMatrix may be generated for a given process node using a layer technology file by a LayerMatrix generator. The layer selection for the generation of the LayerMatrix may be completely customizable. The layer technology file may contain information on the layers and the purpose of the layers. The LayerMatrix may have the physical layers in combination with the layers supported for the given process node. The LayerMatrix may display the possible layer combinations, as shown in FIG. 3A. For example, MET1 and drawing, M1TEXT and drawing, and M1RES and drawing may be identified as shown in the LayerMatrix. Therefore, the LayerMatrix plays a crucial role in the disclosed embodiments. The text present in the LayerMatrix may represent each layer possibility.

In a (typical) PDK/process node, there may be a plurality of physical layers. The physical layers can be classified as Front End of Line (FEOL), Back End of Line (BEOL), and Middle End of Line (MEOL). Apart from the physical layers, there can be, at least one layer put in place for internal Computer-Aided Design (CAD) use, which involves identifying the devices, pins, etc. These marker layers may also be used by diagnostic tools such as Design Rules Checking (DRC), Layout Versus Schematic (LVS), and Parasitic Extraction (PEX). In embodiments shown herein, device recognition, metal, VIA, pin, label, text, and any other specific layers are considered.

FIG. 3B depicts an example of a section of the LayerMatrix along with Sets. The LayerMatrix may comprise a possible combination of three Sets of Set1, Set2, and Set3, each with two columns. Each Set may have a layer and the purpose of the layer as columns. The Set1 may comprise a physical layer and a (possible) purpose of the physical layer. For example, MET1 may be a layer name, and drawings may serve a purpose, as shown in FIGS. 3A and 3B. The Set2 may comprise a (possible) port/label layer and a purpose of the (possible) port/label layer. Therefore, the Set2 may start with a possibility that refers to the possible layer for port recognition. For example, M1TEXT may be a layer name, and drawings may serve a purpose, as shown in FIGS. 3A and 3B. The Set3 may comprise a (possible) device recognition layer and a purpose of the (possible) device recognition layer. For example, M1RES may be a layer name, and drawings may serve a purpose, as shown in FIGS. 3A and 3B. Thus, MET1 may be considered the physical layer, and drawing may be considered the purpose of the MET1 layer, respectively, for Set1 as shown in FIG. 3A. M1TEXT may be considered the possible port/label layer, and drawing may be considered the purpose of the M1TEXT layer, respectively, for Set2 as shown in FIGS. 3A and 3B. M1RES may be considered the possible device recognition layer, and drawing may be considered the purpose of the M1RES layer, respectively, for Set3 as shown in FIGS. 3A and 3B. Since the Set3 also starts with the possibility, for example, there may be more than one layer, so, not all may recognize that device (the same device). But in the LayerMatrix, there will be one that will be recognized. These layers and the purposes of the layers may be specific to the PDK, as mentioned, and they can always be specific to one PDK or one process node.

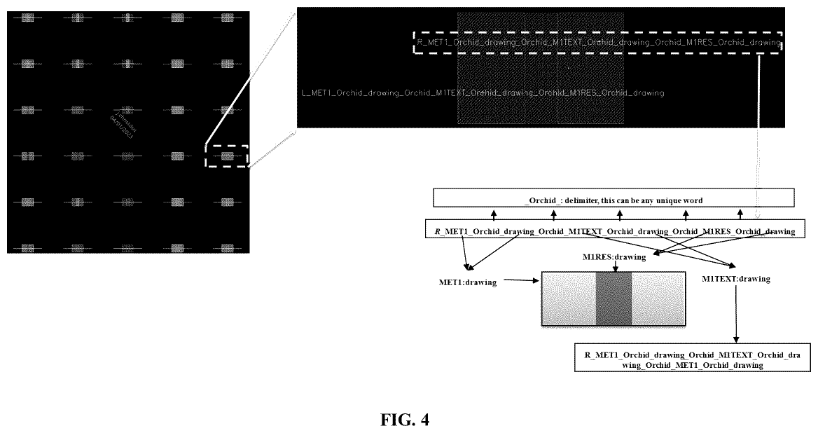

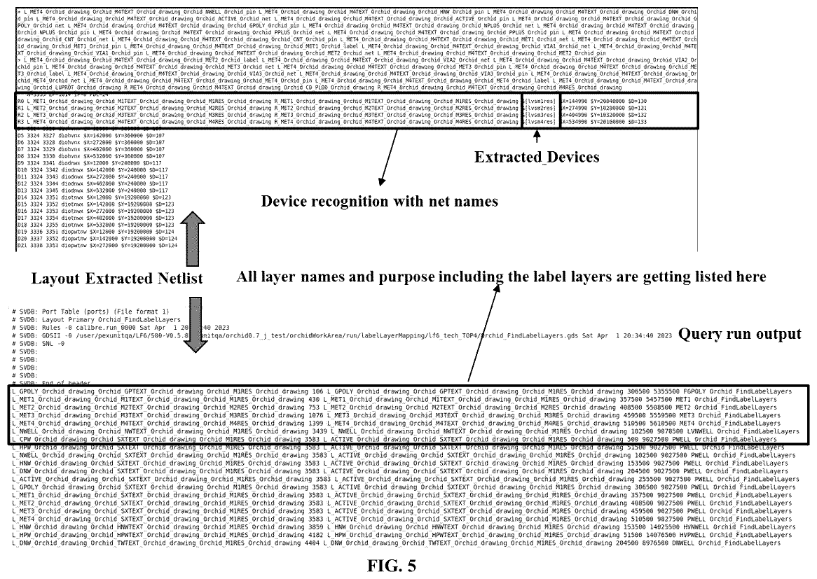

FIG. 4 depicts an example of a section of the GDS. The LayerMatrix may have layer property-specific, unique polygon shapes and label name patterning. A shape generator can generate unique geometries for each element of the LayerMatrix using the generated LayerMatrix. The geometry may be generated in the form of the GDS. In the GDS, each of the shapes seen may be representative of a matrix row in the LayerMatrix. The GDS may be completely representative of the LayerMatrix. Any customization may be possible in LayerMatrix. However, some of the layers (only the necessary layers) may be restricted. Otherwise, the GDS generation can take a longer runtime for all the layers.

Therefore, specific shapes may be generated, and labels may be provided for the specific shapes using all these layers in a standard manner for identification of the purpose of the mentioned layers. Hence, the designs can be made on the EDA (vendor) tool, and that can be translated to another EDA tool as well. Different tools may have different naming patterns. Thus, the GDS layer numbers may be common in different environments and tools (the EDA tools). The PDK defines the GDS layer number for the corresponding layers. The polygons of the GDS may be generated from Set1 and Set3 of each row of the LayerMatrix. The label/text names may be generated from all the Sets (the Set1, Set2, and Set3) of each row of the LayerMatrix, with _Orchid_ as a unique delimiter to differentiate between the layer names and the purpose name of the layer. The polygons and the label/text attached to them may be always the same in the LayerMatrix row. Therefore, the complete GDS format may be as follows: (R_PhysicalLayer_Orchid_PhysicalLayerPurpose_Orchid_PortRecognizationLayer_Orchid_Port RecognizationLayerPurpose_Orchid_DeviceRecognizationLayer_Orchid_DeviceRecognization LayerPurpose).

FIG. 5 depicts an example of a section of a Layout Extracted Netlist (LEN). The physical verification tools are run on the above-generated GDS to extract the layout netlist. FIG. 5 shows a covered area, which is a small section of an outcome, that recognizes some devices, such as LVSM1, LVSM2, LVSM3, LVSRES1, LVSRES2, and so on, and possible devices are identified in the layout. All layers and the purpose of the layers may be listed in the below netlist format in the covered area, as shown in FIG. 5. Thus, the layer can also be identified from the output. For example, device identification refers to the design recognition layer. Therefore, the layout netlist may be unique in terms of the net names and the devices extracted from the GDS. The devices may be recognized by their net names. All layer names and the purpose of the layer, including the label layers, are listed in FIG. 5. The extracted device names as well as net names may be received as an output of the physical verification run. Thus, all possible devices of the process node may be identified in the layout netlist. Device marker layers can be indented. The query run output is shown in FIG. 5. Therefore, different layers with different purposes in a given process node can be identified, such as, but not limited to, net label/label layers/device recognition layers/pins and CAD purpose layers. The CAD purpose layers can be for anything, such as some specific recognition, a specific purpose, or some extra layers getting defined. Therefore, there can be, for example, combinations of hundreds or thousands of layers (e.g., 100, 200, and 1000 layers) because the list is quite large.

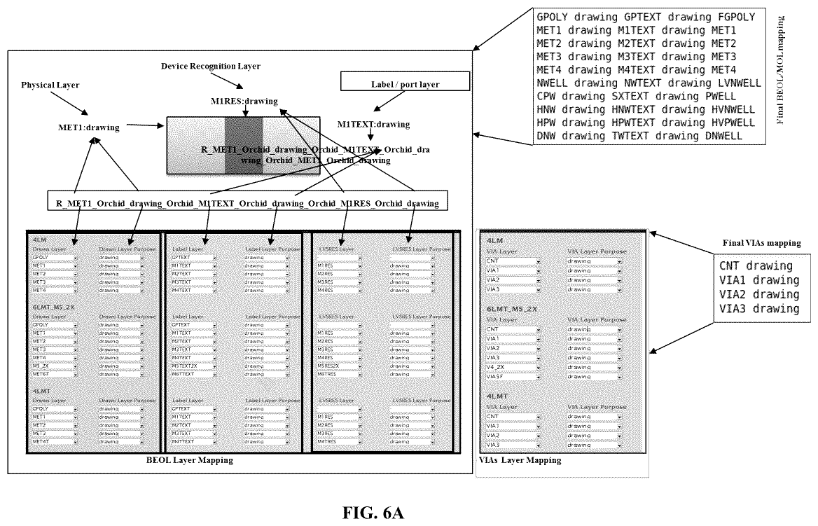

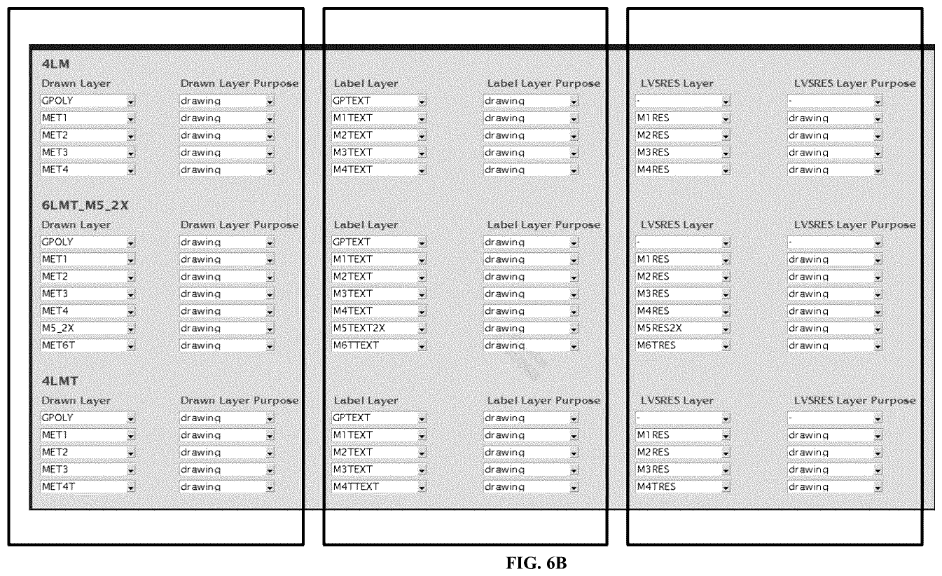

FIG. 6A depicts a layer combination for a process node for device/pin/label recognition in BEOL layer mapping and VIAs layer mapping. The layers may be identified, such as the physical layers and the purpose of the physical layer, the label layers and the purpose of the label layer, and the device recognition layers and the purpose of the device recognition layers, from the extracted unique net names and the extracted devices for each physical layer. Hence, the LayerMatrix may have all combinations of layers. The possible layer combinations may be selected, which are supported for the specific use/purpose. Thus, the possible layer combinations only get extracted into the netlist. The final layers, which are supported, can be seen in a snapshot as shown in FIG. 6. Therefore, the final output may be an exact layer combination and the purpose of the layers, which are used in the process node for device recognition, pin recognition, and label recognition.

The information is extracted, and the device is recognized. For example, MET1 drawing may identified as the physical layer and the purpose (drawing) of the physical layer (MET1). The M1RES drawing layer may be identified as the device recognition layer. Similarly, the label layer information may also get recognized from the complete GDS format (e.g., R_MET1_Orchid_drawing_Orchid_M1TEXT_Orchid_drawing_Orchid_M1RES_Orchid_drawi ng). Thus, the M1TEXT drawing may be recognized as the label layer. Further, the extracted information from these three layers can be put into the GUI for segregation. Similarly, other layers can also be identified using the disclosed method. Other layers can also be identified, such as, but not limited to, metals. The metal layers can be, for example, Metal1, Metal2, Metal3, Metal4, and so on.

FIG. 6B provides an enlarged view of the example depicted in FIG. 6A, wherein the physical layers are shown, such as GPOLY, MET1, MET2, MET3, MET4, and so on, with the purposes (drawings) of the physical layers in the BEOL layer mapping. Similarly, the label layers are shown, such as GPTEXT, M1TEXT, M2TEXT, M3TEXT, M4TEXT, and so on, with the purposes (drawings) of the label layers in the BEOL layer mapping. Similarly, the device layers are shown, such as M1RES, M2RES, M3RES, M4RES, and so on, with the purposes (drawings) of the device layers in the BEOL layer mapping.

Similarly, the VIA layers are shown in FIG. 6A, such as CNT, VIA1, VIA2, VIA3, and so on, with the purposes (drawings) of the layers in the VIAs layer mapping.

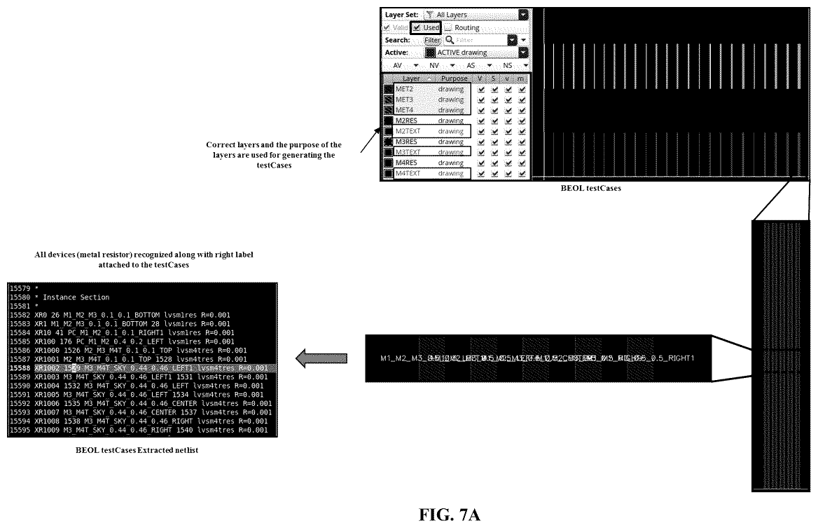

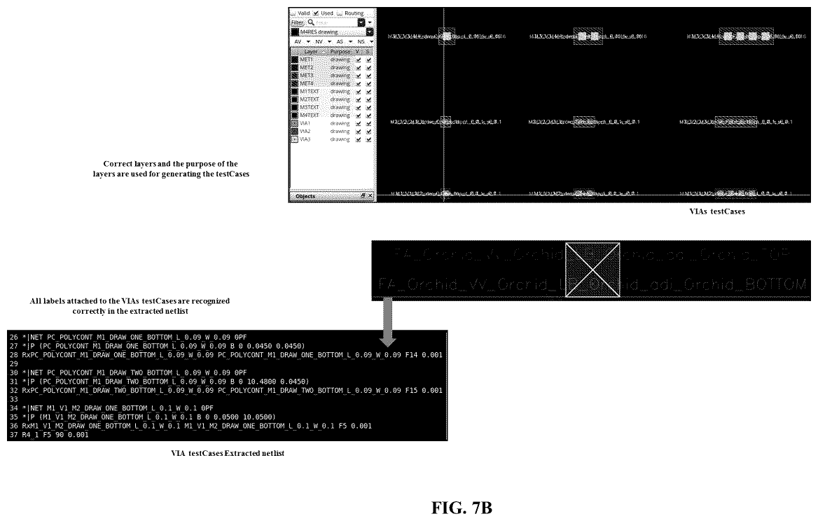

FIG. 7A depicts a use case for the PDK QA testCases generation in a BEOL testCases extracted netlist. There can be different kinds of testCases generated specific to the layers, such as, but not limited to, PEX, BEOL, VIAs, MEOL, and so on. The layers and the purpose of the layers may be used for generating the testCases (BEOL testCases), as shown in FIG. 7A, such as MET2, MET3, MET4, M2TEXT, M3TEXT, M4TEXT, M2RES, M3RES, M4RES, with the purposes (drawings) of all these layers, and so on. All devices (e.g., metal resistors) may be recognized along with a right label attached to the testCases, in a BEOL testCases extracted netlist, as shown in FIG. 7A (for example, 15588 XR1002 1529 M3_M4T_SKY_0.44_LEFT1 lvsm4tres R=0.001). In the example shown herein, MET*:
drawing may be used as a conductor layer (the physical layer and the purpose of the physical layer), M*TEXT: drawing may be used as the label/port layer (the label/port layer and the purpose of the label/port layer), and M*RES: drawing may be used as the device recognition layer (the device recognition layer and the purpose of the device recognition layer). Herein, ‘*’ may be a natural number, such as 1, 2, 3, or 4.

FIG. 7B depicts a use case for the PDK QA testCases generation in a VIAs testCases extracted netlist. The layers and the purpose of the layers may be used for generating the testCases (VIAs testCases), such as MET1, MET2, MET3, MET4, M1TEXT, M2TEXT, M3TEXT, M4TEXT, VIA1, VIA2, VIA3, with the purposes (drawings) of all these layers, and so on. All labels attached to the VIAs testCases may be recognized correctly in the VIAs testCases extracted netlist, as shown in FIG. 7B. In the example shown herein, MET*: drawing may be used as a conductor layer (the physical layer and the purpose of the physical layer), M*TEXT: drawing may be used as the label/port layer (the label/port layer and the purpose of the label/port layer), and M*RES: drawing may be used as the device recognition layer (the device recognition layer and the purpose of the device recognition layer).

The designs used in the VLSI industry can be checked for their qualification, for example, whether they are correctly designed or not with respect to electrical or physical behavior. Once the designs are qualified, they may get fabricated. Therefore, each of the components in the designs must qualify through the PVC (such as LVS, DRC, PEX, and so on) at the time of releasing the PDK. Therefore, the extracted information can be used to make the right combination of the testCases. The layers, labels, pin, port, and device may not be recognized correctly if the wrong label is used. Thus, the generated testCases may not work properly. Once the embodiment knows the layers and the purposes of the layers (e.g., once the layers and the purposes of the layers are recognized), the testCases can be generated automatically, and thereafter, the testCases can be used (may work properly).

At the time of the release of the PDK, one process node may be advanced (proceeded) or switched to another process node during a design layout migration. Thus, the layer numbers can be different for different process nodes. Therefore, these layer numbers need to be mapped correctly. For example, when moving from one building to another, both buildings may not have the same floors and may not have the same architect. Thus, design layout migration is not easy.

For example, when dealing with metals (metal layers), the metal drawing may be used as a conductor layer; thus, in the example shown herein, the physical layer can be such as Metal1, Metal2, Metal3, and so on. The layer that conducts the electricity may also be known as the metal conductor layer. Sometimes there may be a need to define pin A, pin B, and so on, for further recognition. In the example shown herein, MRES (M*RES) may be used for the recognition of metal resistance, and that may be recognized as a metal resister. Therefore, the MRES layer may be used for that purpose.

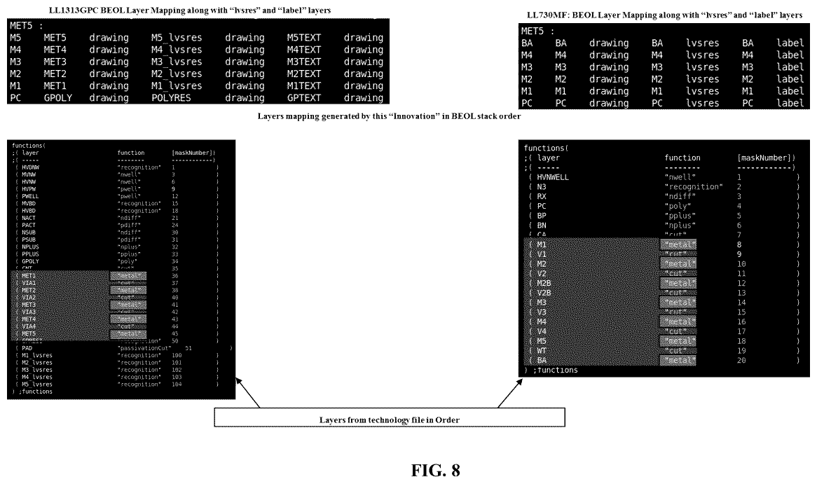

FIG. 8 depicts a use case for the design layout migration for the BEOL layer mapping. The layer mapping may be generated in BEOL stack order. One process is called LL1313GPC, and the other process is called LL730MF, for the BEOL layer mapping, along with “lvsres” and “label” layers, as shown in FIG. 8. In the process LL1313GPC, the BEOL layers may be such as, MET1, MET2, MET3, MET4, MET5, and so on, whereas in the process LL730MF, the BEOL layers may be such as M1, M2, M3, M4, and so on. M5 is not present in the process LL730MF, as shown in FIG. 8. In an embodiment shown herein, the order of the layer's name can be changed. In the process LL1313GPC, for M5, the layer name is MET5 drawing, the device recognition layer name is M5 lvsres drawing, and the label layer name is M5TEXT drawing, as shown in FIG. 8. Thus, the M5 drawing must have this M5 label only for recognition. Similarly, in the process of LL730MF for another process node, the names change. The layer name MET5 in the process LL1313GPC may get aligned to BA in the process LL730MF. Hence, this information may not be automatically available, and there may be a need to go through the text, layers, and documents manually. The disclosed embodiment of the inventive concepts can recognize these layers (without manual review). The embodiment knows (has information of) which layer is being used for what purpose and what the sequence of these layers is. In the design layout migration process, the embodiment can make and enable the method to find out all these layers automatically and align the mapping, and thereafter, the migration is performed smoothly, which helps significantly to make the design layout migration flow from one process node to another. Therefore, the layer names can be different in the different process nodes due to different naming conventions (e.g., M1TEXT: drawing->M1: label). For example, layers may be shown, such as MET2, VIA2, MET3, VIA3, and so on, in the process LL1313GPC, and M1, V1, M2, V2, and so on, in the process LL730MF, from a technology file in FIG. 8.

Embodiments of the inventive concepts herein disclose a key solution for design layout migration, as the embodiments may enable grabbing the complete layer/label mapping usage of the original PDK as well as the target PDK through the demonstrated method. For example, if one chip has 10,000 devices or even 10 trillion devices, dealing manually with those (mapping those devices) may be near impossible. Thus, the design layout migration case is very important in those cases. The other thing is, from one process node to another, these layer names may not be standardized. As the embodiments are shown herein, the key and the layer map file, which have all these mappings correctly done after performing the physical verification runs, can enable the design layout migration (very easily). Further, the embodiment shown herein discloses the LayerMatrix and labels for testCases generation, and the method to identify the use and purpose of the layers from the physically extracted ports is not available in the conventional approaches. There are certain advantages, such as, but not limited to, identification of usages and the purpose of the layers in the PDK, reduced Turn Around Time (TAT) as no manual effort is needed to identify the usage and purpose of the layers, and so on.

Consider that there is a need to read all the documents. Sometimes the documents may have 200-300 pages or maybe 1000 pages. For example, there are 100 s of different PDKs and process nodes and 1000 s of layers. Thus, if an average consideration is for 500 layers for each process node, one person cannot understand and remember all of these. Thus, this works on non-standard layer naming conventions in PDK as well. The disclosed embodiment may provide an error-proof solution. Uses of the embodiments of the inventive concepts can be extended (applied) in various other domains, like design layout migration. Various types of testCases may be generated for the PDK or other groups, as well as design layout automation. Thus, design layout automation may be the key in this industry. Various tools are available in the market, depending on the connectivity provided. It makes the design layout automatic and provides the label and recognition of everything automatically using the information. They seek the information for the purpose. Therefore, the information can come automatically using the disclosed method. Other advantages include, but not limited to, usages that can extend to various design flows, design layout migration from one process node to another (StdCell, SRAM, IPs, etc.), various types of the testCases generation for PDK components QA, design layout automation (StdCell, SRAM, IPs, etc.), and so on.

Therefore, as a result, in the embodiments shown herein, the layers can be identified, and the identified layers can be used for getting a label. The design layout automation can be correctly recognized by the LVS tool, once it has been done. Thus, the highlighted labels may be one kind of pattern and can be used for testCases, that part is recognized correctly. The device may also get recognized correctly. Therefore, there can be different stages of the testCases generation, such as label being recognized after one LVS run; further, the query can also be recognized. Further, the final parasitic extraction happens here and gets recognized correctly.

In the case of the VIA test cases, the VIA testCases can be bottom metal and top metal. The VIA testCases may not be recognized by the labels, and the labels may have to be put on the metals only, top or bottom. After that, these VIA testCases can be used. The next VIA testCases can be recognized after the recognition of the labels and by the LVS tool and the extraction tool. Therefore, two things are important. One is the label, and another is the recognition of the parasitic. Thus, those metals can be recognized as metal resistance devices. There are three important things, as follows: One is to identify the metals (metal layers); for example, these are Metal1, Metal2, Metal3, Metal4, Metal5, and so on. The second is that each metal can define that recognition layer to define a MetalRES as the device recognition layer. The third one is to get the right label, which can also be created automatically using the LVS tool or an extension tool, once the label has been recognized. There may be, for example, thousands of combinations of testCases for the metals, and all those things get recognized with the LVS tool. Thus, all combinations of testCases may not be visible, but a small part of them can be taken.

The embodiments disclosed herein can be implemented through at least one software program running on at least one hardware device and performing network management functions to control the elements. The elements can be at least one of hardware devices, or a combination of hardware device and software module.

The embodiment disclosed herein describes a device and methods for identifying the purpose of the GDS layers used in the layout design. Therefore, it is understood that the scope of the invention may include a program and a computer readable mean having a message therein. Such computer readable storage mean may contain program code mean for implementation of one or more steps of the method, when the program runs on a server or mobile device or any suitable programmable device. The method is implemented in at least one embodiment through or together with a software program written in e.g., Very high speed integrated circuit Hardware Description Language (VHDL) or in another programming language, or implemented by one or more VHDL or several software modules being executed on at least one hardware device. The hardware device can be any kind of (portable) device that can be programmed. The device may also include means which could be e.g., hardware means like e.g., an ASIC, or a combination of hardware and software means, e.g., an ASIC and an FPGA, or at least one microprocessor and at least one memory with software modules located therein. The method embodiments described herein may be implemented partly in hardware and partly in software. In some embodiments, the invention may be implemented on different hardware devices, e.g., using a plurality of CPUs.

The foregoing description of the specific embodiments will reveal the general nature of the embodiments herein that others can, by applying current knowledge, readily modify and/or adapt for various applications such specific embodiments without departing from the generic concept, and, therefore, such adaptations and modifications should and are intended to be comprehended within the meaning and range of equivalents of the disclosed embodiments. It is to be understood that the phraseology or terminology employed herein is for the purpose of description and not of limitation. Therefore, while the embodiments herein have been described in terms of at least one embodiment, those skilled in the art will recognize that the embodiments herein can be practiced with modification within the scope of the embodiments as described herein.

We claim:

1. A method for identifying a purpose of at least one Graphic Design System (GDS) layer used in a layout design, comprising:
generating, by an electronic device, a LayerMatrix using a layer technology file, wherein the layer technology file includes layer information;
generating, by the electronic device, a polygon shape and a label using a set in the LayerMatrix, wherein the set includes a layer and a purpose of the layer;
generating, by the electronic device, a GDS using the polygon shape and the label in the LayerMatrix;
extracting, by the electronic device, a layout netlist from the GDS using a layout netlist extraction process;
filtering out, by the electronic device, a list from the layout netlist based on a designed labelling pattern, wherein the list includes label information, port information, and device information; and
mapping, by the electronic device, the list to the layer information in the layer technology file.

2. The method as claimed in claim 1, wherein the set includes a first set, a second set, and a third set,
wherein the LayerMatrix comprises possible combinations of the first set, the second set, and the third set with two columns, and
wherein the possible combinations comprise the layer with the purpose of the layer in the layout design.

3. The method as claimed in claim 2, wherein the first set comprises a physical layer and a possible purpose of the physical layer, the second set comprises a possible label layer and a purpose of the possible label layer, and the third set comprises a possible device recognition layer and a purpose of the possible device recognition layer.

4. The method as claimed in claim 2, wherein the generating, by the electronic device, the polygon shape and the label includes generating the polygon shape using the first set and the third set.

5. The method as claimed in claim 2, wherein the generating, by the electronic device, the polygon shape and the label includes generating the label using the first set, the second set, and the third set with a delimiter.

6. The method as claimed in claim 1, wherein the generating, by the electronic device, the polygon shape and the label, comprises assigning, by the electronic device, the label to the polygon shape.

7. The method as claimed in claim 1, wherein the generating, by the electronic device, the GDS comprises a translation of the polygon shape into a GDS format and a translation of the label into a GDS format.

8. The method as claimed in claim 1, wherein the electronic device includes a Layout Versus Schematic (LVS) tool, and
wherein the LVS tool is configured to perform the layout netlist extraction process.

9. The method as claimed in claim 1, wherein the mapping, by the electronic device, the list to the layer information in the layer technology file, comprises:
separating, by the electronic device, a plurality of layer names and layer numbers from the list; and
mapping, by the electronic device, the plurality of layer names and the layer numbers to the layer information in the layer technology file.

10. An electronic device, comprising:
a processor;
a communication module; and
a memory module,
wherein the processor is electrically connected to the memory module, and
wherein the processor is configured to:
generate a LayerMatrix using a layer technology file, wherein the layer technology file includes layer information;
generate a polygon shape and a label using a set in the LayerMatrix, wherein the set includes a layer and a purpose of the layer;
generate a Graphic Design System (GDS) using the polygon shape and the label in the LayerMatrix;
extract a layout netlist from the GDS using a layout netlist extraction process;
filter out a list from the layout netlist based on a designed labelling pattern, wherein the list includes label information, port information, and device information; and
map the list to the layer information in the layer technology file.

11. The electronic device as claimed in claim 10, wherein the communication module is configured to enable the electronic device to communicate with an external device.

12. The electronic device as claimed in claim 10, wherein the set includes a first set, a second set, and a third set,
wherein the LayerMatrix comprises possible combinations of the first set, the second set, and the third set with two columns, and
wherein the possible combinations comprise the layer with the purpose of the layer.

13. The electronic device as claimed in claim 12, wherein the first set comprises a physical layer and a possible purpose of the physical layer, the second set comprises a possible label layer and a purpose of the possible label layer, and the third set comprises a possible device recognition layer and a purpose of the possible device recognition layer.

14. The electronic device as claimed in claim 12, wherein the processor is further configured to generate the polygon shape from the first set and the third set of each row of the LayerMatrix.

15. The electronic device as claimed in claim 12, wherein the processor is further configured to generate the label from the first set, the second set, and the third set of each row of the LayerMatrix with a delimiter.

16. The electronic device as claimed in claim 10, wherein the processor is further configured to assign the label to the polygon shape.

17. The electronic device as claimed in claim 10, wherein the processor is further configured to translate the polygon shape into a GDS format and to translate the label into a GDS format.

18. The electronic device as claimed in claim 10, further comprising:
a Layout Versus Schematic (LVS) tool,
wherein the LVS is configured to perform the layout netlist extraction process.

19. The electronic device as claimed in claim 10, wherein the processor is further configured to separate a plurality of layer names and layer numbers from the list and to map the plurality of separated layer names and layer numbers to the layer information in the layer technology file.

20. The electronic device as claimed in claim 19, wherein the processor is further configured to assign the label to the one or more polygon shapes.
